(19) United States
(12) Patent Application Publication
(10) Pub. No.: US 2018/0197993 A1
(43) Pub. Date: Jul. 12, 2018

(54) SEMICONDUCTOR DEVICE AND A METHOD OF MANUFACTURING THE SAME

(71) Applicant: INSTITUTE OF MICROELECTRONICS, CHINESE ACADEMY OF SCIENCES, Beijing (CN)

(72) Inventors: Jun LUO, Beijing (CN); Chao ZHAO, Kessel-lo (BE); Shi LIU, Beijing (CN)

(21) Appl. No.: 15/849,217

(22) Filed: Dec. 20, 2017

(30) Foreign Application Priority Data
Jan. 10, 2017 (CN) 201710017569.2

(51) Int. Cl. H01L 29/78; H01L 29/45; H01L 29/167; H01L 29/66; H01L 21/311; H01L 21/265; H01L 21/285; H01L 21/321

(52) U.S. Cl. CPC H01L 29/7851; H01L 29/456; H01L 29/167; H01L 29/66795; H01L 29/665; H01L 21/26506; H01L 21/26513; H01L 21/28518; H01L 21/3212; H01L 21/31111

(57) ABSTRACT

The present invention relates to a semiconductor device and a method of manufacturing the same. There is provided a semiconductor device comprising: a semiconductor substrate with a fin; a gate intersecting with the fin and a source region and a drain region within the fin at both sides of the gate; metal silicides formed at the source region and the drain region and in contact with the source region and the drain region respectively; wherein there is a impurity dopant at a interface of the metal silicide in contact with the source/drain region, which is capable of reducing a Schottky barrier height between the metal silicide and the source/drain region. The provided semiconductor device can reduce the Schottky barrier height between the metal silicide and the source/drain region, thereby reducing the specific resistance of the contact.

### TECHNICAL FIELD

This disclosure relates to the field of semiconductors, and in particular, to a semiconductor device and a method of manufacturing the same.

### BACKGROUND

As planar semiconductor devices become smaller and smaller, short-channel effects become more pronounced. For this reason, stereoscopic semiconductor devices such as FinFETs (fin field effect transistors) have been proposed. In general, a FinFET includes a fin vertically formed on a substrate and a gate intersecting the fin.

As FinFETs become smaller and smaller, the parasitic resistances of the source and drain in series increase the performance of the entire device. In order to improve the performance of the device, the source-drain series parasitic resistance needs to be further reduced. At the same time, as the size of the FinFET becomes smaller and smaller, the contact resistance of the source/drain region occupies more and more portion of the entire source/drain series parasitic resistance, so lowering the contact resistance of the source/drain region will significantly reduce the source/drain Series parasitic resistance. Therefore, further reduction of the specific resistance ( [symbol] ) of the contact will be the goal pursued by those skilled in the art.

In the current mainstream FinFET process, a metal silicide/silicon contact is generally used to form the contact of the source/drain region. For example, titanium silicide (TiSiₓ) and n-type doped silicon (n-Si) are used to form TiSiₓ/n-Si contact of the source/drain region.

In order to further reduce the specific resistance ( [symbol] ) of the metal silicide/silicon contact, in the current mainstream processes, one skilled in the art can increase the doping concentration in the silicon to reduce the specific resistance ( [symbol] ) of the metal silicide/silicon contact. That is, various ways (e.g., in-situ doping with P (Si: P), dynamic surface annealing (DSA), etc.) are used to increases the impurity activation concentration, thereby decreasing the specific resistance ( [symbol] ) of the metal silicide/silicon contact. In fact, since the metal silicide/silicon contact is a Schottky contact, the Schottky barrier height also significantly affects the specific resistance ( [symbol] ). For example, the Fermi level of the TiSiₓ/n-Si contact is pinned in the middle of the bandgap so that the Schottky barrier height to electrons is high, e.g., about 0.6 eV. Therefore, a higher Schottky barrier height prevents further reduction of the specific resistance ( [symbol] ) of the metal silicide/silicon contact.

Therefore, there is a need to provide a semiconductor device that reduces the Schottky barrier height between the metal silicide and the source/drain region.

### SUMMARY

In view of this, it is an object of the present disclosure to provide, at least in part, a semiconductor device having a reduced Schottky barrier height between a metal silicide and a source region and a drain region and a method of manufacturing the same.

According to an aspect of the present disclosure, there is provided a semiconductor device comprising: a semiconductor substrate with a fin; a gate intersecting with the fin and a source region and a drain region within the fin at both sides of the gate; metal silicides formed at the source region and the drain region and in contact with the source region and the drain region respectively; wherein there is a impurity dopant at a interface of the metal silicide in contact with the source/drain region, which is capable of reducing a Schottky barrier height between the metal silicide and the source/drain region.

Further, the impurity dopant comprises at least one selected from the group consisting of C, Ge, N, P, As, O, S, Se, Te, F, Cl.

According to another aspect of the present disclosure, there is provided a method of manufacturing a semiconductor device, comprising: forming a fin on a semiconductor substrate; forming a gate intersecting with the fin; forming a source region and a drain region in the fin at both sides of the gate; depositing a dielectric on the fin; etching the dielectric to form a contact trench over the source region and the drain region respectively, thereby exposing at least a portion of the upper surface of the source region and the drain region; making an amorphization process on at least part of the exposed upper surface through the contact trench; making an impurity dopant implantation to the at least part of the exposed upper surface through the contact trench; depositing a metal in the contact trench and performing an anneal to form a metal silicide after the impurity dopant implantation; wherein the impurity dopant is capable of reducing a Schottky barrier height between the metal silicide and the source/drain region.

Further, the implanted impurity dopant is segregated at the interface between the metal silicide and the source/drain region during annealing so as to reduce the Schottky barrier height between the metal silicide and the source/drain region.

Further, the amorphous silicon region formed after the amorphization process has a depth of 10 nm or less.

Further, after annealing, the amorphous silicon disappears by reacting with the deposited metal and/or by solid-phase epitaxial regrowth (SPER).

According to an embodiment of the present disclosure, the Schottky barrier height between the metal silicide and the silicon in the source/drain region is reduced due to the presence of impurity dopants at the contact interface therebetween, thereby reducing the specific resistance of the contact, reducing the source/drain series parasitic resistance, and improving the device performance.

### BRIEF DESCRIPTION OF THE DRAWINGS

The above and other objects, features and advantages of the present disclosure will become more apparent from the following description of the embodiments of the present disclosure with reference to the attached drawings, in which:

FIG. 1 shows an example FinFET according to the prior art;

FIGS. 2-10 are schematic cross-sectional views illustrating stages in a flow for manufacturing a semiconductor device taken in the A-A′ direction in FIG. 1 according to an embodiment of the present disclosure.

Throughout the drawings, the similar reference numerals indicate the similar components.

### DETAILED DESCRIPTION

Hereinafter, embodiments of the present disclosure will be described with reference to the accompanying drawings. It should be understood, however, that these descriptions are illustrative only and not intended to limit the scope of the disclosure. In addition, in the following description, descriptions of well-known structures and techniques are omitted to avoid unnecessarily obscuring the concepts of the present disclosure.

Various structural diagrams according to embodiments of the present disclosure are shown in the accompanying drawings. The drawings are not necessarily to scale, with some details being exaggerated for clarity and some details being omitted. The various regions shown in the drawings, the shapes of the layers, and their relative sizes, positional relationships, are merely exemplary and in practice may vary due to manufacturing tolerances or technical limitations, and a person skilled in the art can additionally design regions/layers with different shapes, sizes, relative positions as desired.

In the context of the present disclosure, when a layer/element is referred to as being “on” another layer/element, the layer/element may be directly on another layer/element or there may be a interventing layer/element. In addition, if the layer/element is positioned “on” another layer/element in an orientation, the layer/element can be “under” the other layer/element when the orientation is reversed.

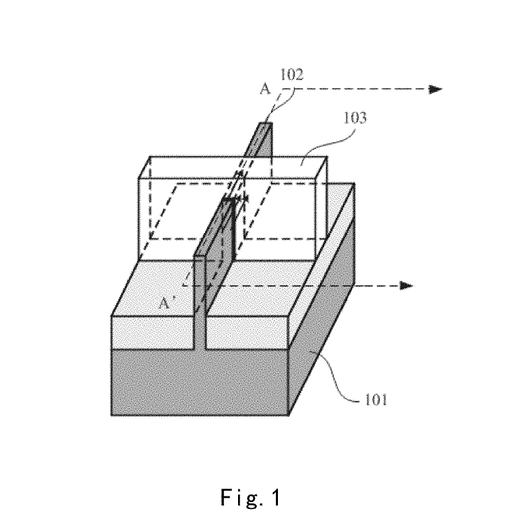

A perspective view of an example FinFET of the prior art is shown in FIG. 1. As shown in FIG. 1, the FinFET includes a substrate 101, a fin 102 formed on the substrate 101, a gate 103 intersecting with the fin 102, a gate dielectric layer disposed between the gate 103 and the fin 102, and an isolation layer. In this example, the fin 102 is integral with the substrate 101 and is comprised of a portion of the substrate 101. In the FinFET, under the control of the gate 103, a conductive channel may be formed in the fin 102, specifically in three sidewalls of the fin 102 (left and right sidewalls and top wall in the figure) as shown by arrows in FIG. 1. That is, the portion of the fin 102 under the gate 103 serves as a channel region, and the source region and the drain region are respectively located at two sides of the channel region.

According to an embodiment of the present disclosure, there is provided a semiconductor device with a fin (for example, a FinFET, particularly a 3D FinFET). The semiconductor device may include a semiconductor substrate with a fin; a gate intersecting with the fin; and a source region and a drain region within the fin at both sides of the gate; metal silicides formed at the source region and the drain region and in contact with the source region and the drain region respectively; wherein there is a impurity dopant at a interface of the metal silicide in contact with the source/drain region, which is capable of reducing a Schottky barrier height between the metal silicide and the source/drain region.

The impurity dopant is segregated at the interface between the metal silicide and the source/drain region during annealing so as to reduce the Schottky barrier height between the metal silicide and the source/drain region.

The impurity dopant comprises at least one selected from the group consisting of C, Ge, N, P, As, O, S, Se, Te, F, Cl.

The gate comprises a high-K gate dielectric and a metal gate conductor.

The metal silicide comprises titanium silicide.

The present disclosure may be embodied in various forms, some of which are described below, and the following description of the silicon-based material will be given below for the sake of convenience.

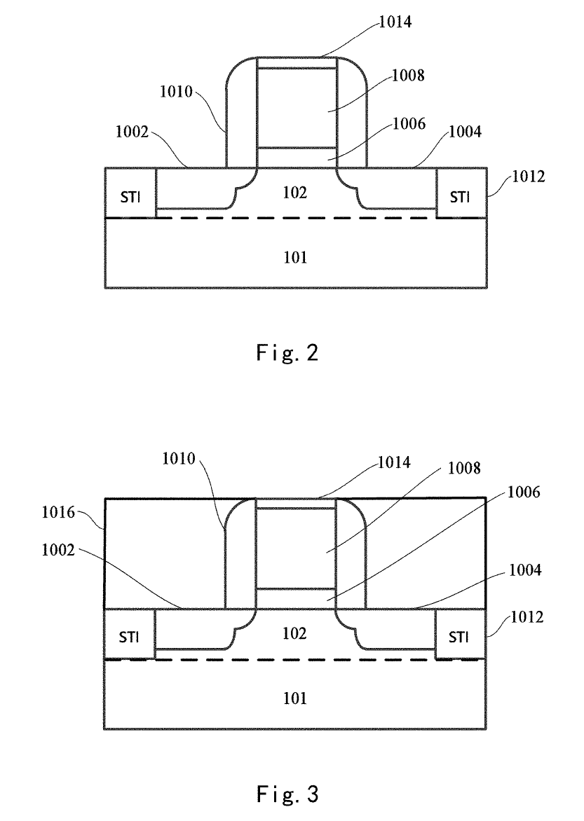

FIGS. 2-10 are schematic cross-sectional views illustrating stages in the flow for manufacturing a semiconductor device according to an embodiment of the present disclosure.

As shown in FIG. 2, a semiconductor substrate 101 is provided. Fin 102 are formed on the semiconductor substrate 101. The fin 102 is integral with the substrate 101 and is made up of a portion of the substrate 101. FIG. 2 shows a cross-sectional view taken in the direction of the longitudinal extension of the fin (i.e., in the A-A′ direction in FIG. 1). A sacrificial gate stack that intersects with the fin may be formed above the substrate 101. The sacrificial gate stack may include a sacrificial gate dielectric layer 1006, a sacrificial gate conductor 1008, and a cap layer 1014 sequentially formed. The semiconductor substrate 101 includes, for example, a silicon wafer, the sacrificial gate dielectric layer 1006 includes, for example, an oxide, and the sacrificial gate conductor 1008 includes, for example, poly silicon. After formation of the sacrificial gate stack, ion implantation may be performed (formation of a source/drain, etc.), a spacer may be formed, and the like. Specifically, ion implantation is performed in the fin at both sides of the sacrificial gate stack to form the source region 1002 and the drain region 1004, respectively. The source region 1002 and the drain region 1004 include, for example, n-type doped silicon (n-Si). A gate spacer layer 1010 is formed on the sidewall of the sacrificial gate stack. The gate spacer layer 1010 may include a single layer or a multi-layer configuration, and may include any one of various suitable dielectric materials such as SiO₂, Si₃N₄, SiON, or a combination thereof. In addition, a shallow trench isolation (STI) 1012 may be formed outside the source region 1002 and the drain region 1004, respectively, for device isolation.

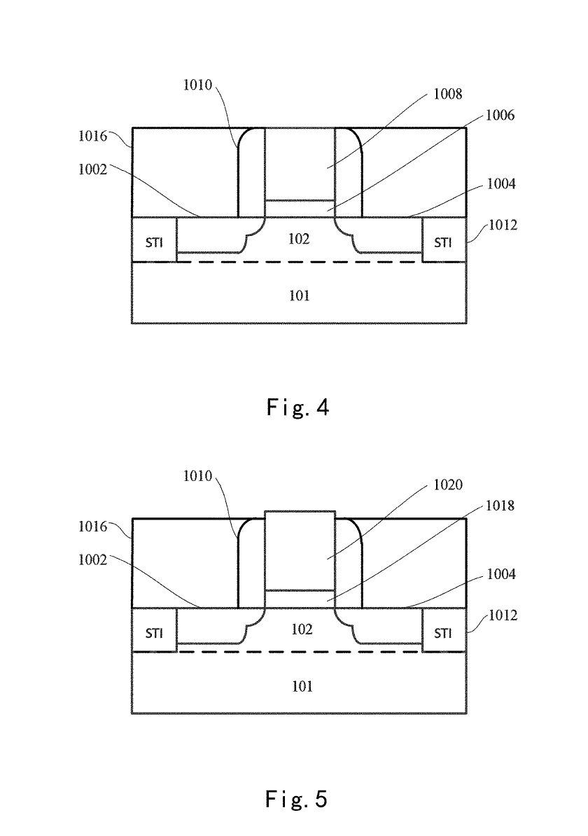

After the above process is completed, as shown in FIG. 3, a dielectric layer 1016 is deposited over the fin, thereby covering the entire source region 1002 and drain region 1004. The dielectric layer 1016 may include any of various suitable dielectric materials such as SiO₂, Si₃N₄, SiON, or a combination thereof. In the case of using an alternative gate process, as shown in FIG. 4, the dielectric layer 1014 may be planarized, such as chemical mechanical polishing (CMP). CMP can proceed until the sacrificial gate conductor 1008 is exposed.

In this way, an alternative gate process can then be applied to form the final gate stack. Specifically, for example, the sacrificial gate conductor 1008 may be removed by selective etching and the sacrificial gate dielectric layer 1006 may optionally be removed to form a gate trench inside the gate spacer 1012. In the gate trench, a actual gate dielectric layer and a actual gate conductor can be sequentially formed, for example, by a deposition and etch back process. Specifically, as shown in FIG. 5, a gate dielectric layer 1018 and a gate conductor 1020 are sequentially formed on the fin 102. The gate dielectric layer 1018 may include any one of high K gate dielectric such as HfO₂, HfSiO, HfSiON, HfTaO, HfTiO, HfZrO, Al₂O₃, La₂O₃, ZrO₂, LaAlO, or a combination thereof and the gate conductor layer 1020 may include a metal gate conductor such as Ti, Co, Ni, Al, W or alloys or metal nitrides thereof. In addition, the gate dielectric layer 1020 may further include a thin oxide (a high-K gate dielectric is formed on the oxide). A work function adjusting layer (not shown in the figure) may also be formed Between the gate dielectric layer 1006 and the gate conductor 1008.

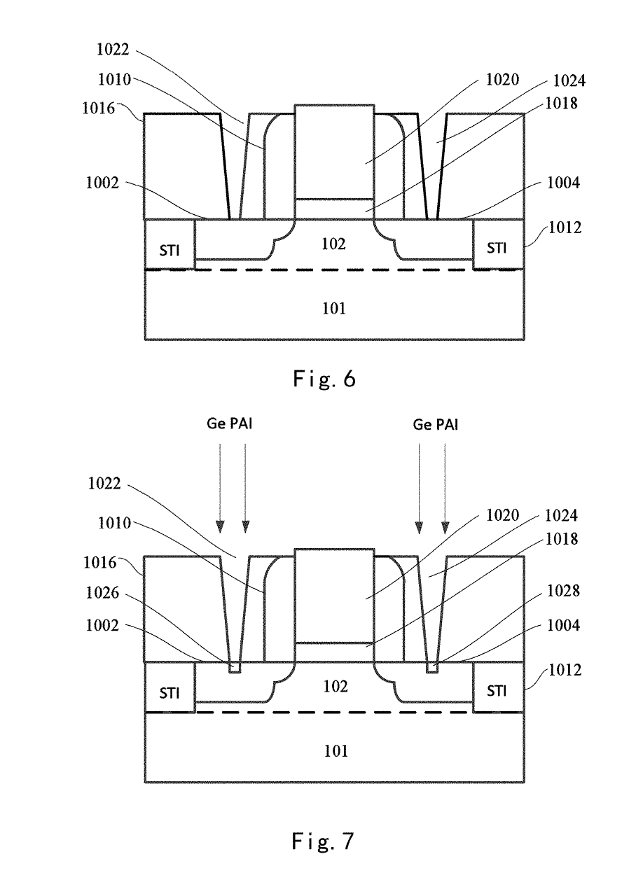

After the gate dielectric layer 1018 and the gate conductor 1020 are formed, as shown in FIG. 6, an anisotropic etching process (for example, plasma etching, reactive ion etching and the like) is performed on the dielectric layer 1016 to form openings, thereby forming contact trenches 1022 and 1024 above the source region 1002 and the drain region 1004 respectively to expose part of the upper surface of the source region 1002 and the drain region 1004.

After forming the contact trenches 1022 and 1024, as shown in FIG. 7, the exposed part of the upper surfaces of the source region 1002 and the drain region 1004 are amorphized through the contact trenches 1022 and 1024 to form amorphization regions in the source region 1002 and the drain region 1004 under the contact trenches 1022 and 1024 respectively. For example, the amorphization process can be performed as follows. Specifically, germanium ion implantation (i.e., Ge pre-amorphization ion implantation (PAI)) may be performed, which amorphizes a superficial (<10 nm) surface of the source region 1002 and the drain region 1004, thereby forming amorphization regions. The amorphous regions may also be formed by pre-amorphized ion implantation of Ge or Si. In the case where the source region 1002 and the drain region 1004 include n-type doped silicon, the amorphized regions are formed as the amorphous silicon regions 1026 and 1028.

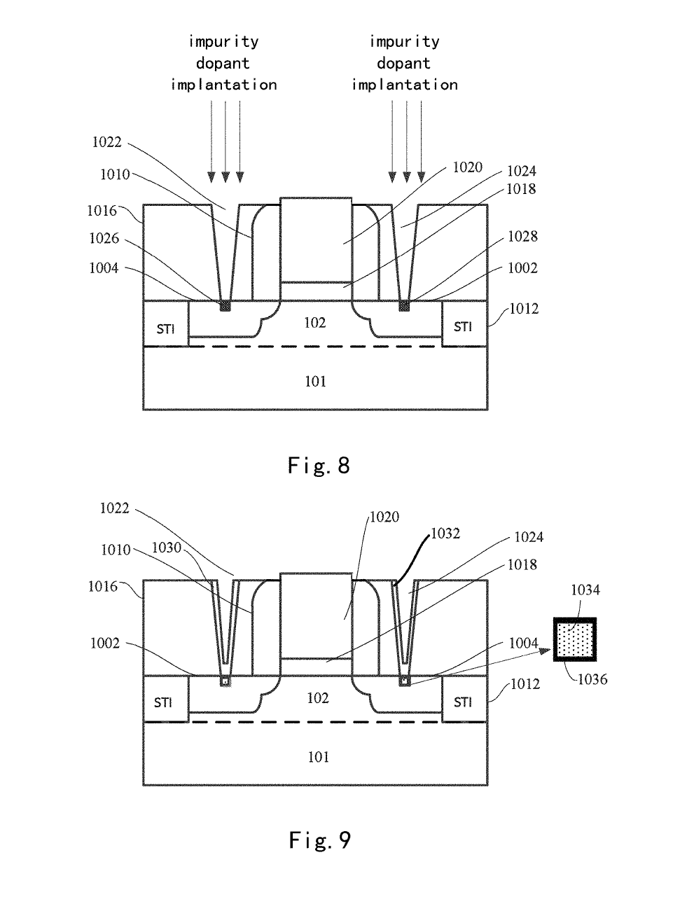

After the amorphous silicon regions 1026 and 1028 are formed, as shown in FIG. 8, the formed amorphous silicon regions 1026 and 1028 are implanted with a impurity dopant through the contact trenches 1022 and 1024. The impurity dopant includes at least one selected from the group consisting of C, Ge, N, P, As, O, S, Se, Te, F, Cl. The implantation energy for impurity dopant implantation is between 0.5 keV and 5 keV. The implanted impurity dopant enters the amorphous silicon regions 1026 and 1028, and most of the impurity dopants are confined in the amorphous silicon regions 1026 and 1028.

After the impurity dopant implantation is completed, as shown in FIG. 9, metal layers 1030 and 1032 are deposited in the contact trenches 1022 and 1024, and annealing is performed to form metal silicide in the amorphous silicon regions 1026 and 1028, and thus the contact of the metal silicide with the n-type doped silicon of the source/drain region is formed. The deposited metal may include Ti/TiN, and thus, the formed metal silicide may include titanium silicide (TiSiₓ). In this case, the contact between titanium silicide and n-type doped silicon (TiSiₓ/n-Si) is formed.

In a conventional mainstream process, in order to reduce the contact resistance between the metal silicide and the n-type doped silicon in the source/drain region, various methods are used to increase the doping concentration in n-type doped silicon such as in-situ doping P (Si: P), dynamic surface annealing (DSA) and so on to improve the impurity activation concentration. However, the Schottky barrier height to electrons is high, e.g., about 0.6 eV, due to the Fermi level of the titanium silicide/n-type doped silicon contact being pinned in the middle of the band gap. Therefore, in order to further reduce the contact resistance between titanium silicide and n-type doped silicon, in addition to increasing the doping concentration in n-type doped silicon, it is also necessary to reduce the Schottky barrier height between titanium silicide and n-type doped silicon.

In accordance with the principles of the present invention, since the impurity dopant implantation was previously performed on the amorphous silicon regions 1026 and 1028, during the formation of the metal silicide, the implanted impurity dopant is segregated at the interface between the metal silicide and the source/drain region during annealing so as to reduce the Schottky barrier height between the metal silicide and the source/drain region. Specifically referring to the enlarged view at the right side of FIG. 9, as the titanium reacts with the amorphous silicon to form the titanium silicide 1034, the implanted impurity dopant is segregated at the interface between the titanium silicide and the n-type doped silicon, the segregated impurity dopant 1036 will cause a reduced Schottky barrier height. Therefore, it is possible to reduce the contact resistance between titanium silicide and n-type doped silicon, that is, to reduce the specific resistance (^{ρ}_{c}) of the contact between titanium silicide and n-type doped silicon.

In addition, the amorphous silicon of the amorphous silicon regions 1026 and 1028 disappears after annealing by reacting with the deposited metal and/or by solid-phase epitaxial regrowth (SPER). Specifically, as described above, during annealing, amorphous silicon reacts with titanium to form titanium silicide while at least a portion of the amorphous silicon regrows into crystalline silicon. Therefore, after annealing, the amorphous silicon of the amorphous silicon regions 1026 and 1028 disappears by reacting with titanium and/or by regrowth.

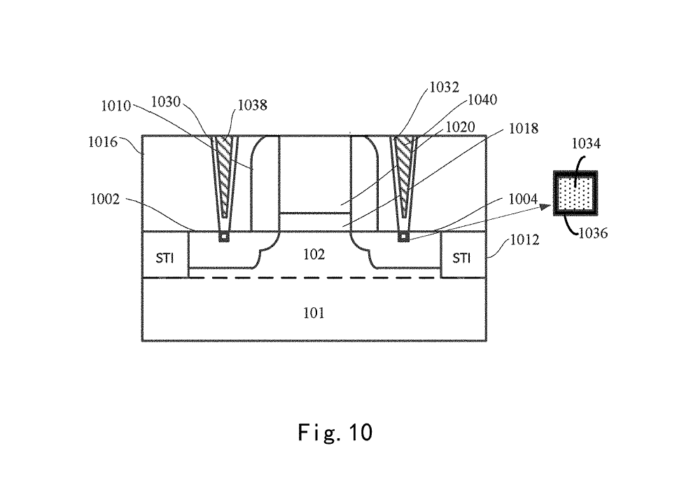

After forming the contact between the metal silicide and the source/drain region with a reduced Schottky barrier height, as shown in FIG. 10, the method may further include forming a contact plug in the contact trenches. For example, tungsten (W) may be deposited within contact trenches 1022 and 1024 to form tungsten (W) layers 1038 and 1040 on the deposited metal layers (e.g., Ti/TiN) 1030 and 1032, respectively. The upper surfaces of the tungsten layers 1038 and 1040 are then planarized. The tungsten layers can be used as contact plugs.

Thus, the semiconductor device according to the embodiment of the present disclosure is obtained. As shown in FIG. 10, the semiconductor device may include a semiconductor substrate 101 with a fin; a gate dielectric 1018 and a gate conductor 1020 (which constituting a gate stack) formed on the fin 102; a gate spacers 1010 formed on both the left and right sidewalls of the gate stack, and a source region 1002 and a drain region 1004 formed in the fin at both sides of the gate stack. Dielectric material 1016 is formed over fin 102. Dielectric material 1016 covers the source region 1002 and the drain region 1004 and contact trenches are formed therein to expose at least a portion of the upper surface of the source region 1002 and the drain region 1004. Metal layers (e.g., Ti/TiN) 1030 and 1032 and tungsten layers 1038 and 1040 are sequentially formed in the contact trenches. Metal layers (e.g., Ti/TiN) 1030 and 1032 form metal silicide 1034 at the source 1002 and the drain region 1004, respectively. There is a impurity dopant at the interface of Metal silicide 1034 with the source region 1002/the drain region 1004. The segregated impurity dopant 1036 significantly reduces Schottky barrier height between the metal silicide 1034 and the n-type doped silicon of the source region 1002 or the drain region 1004, thereby effectively reducing the specific resistance ^{ρ}_{c} of the contact.

In the above description, the technical details of patterning and etching of the layers are not described in detail. However, it will be understood by those skilled in the art that layers, regions, etc. of the desired shape may be formed by various technical means. In addition, in order to form the same structure, those skilled in the art can also design methods that are not completely the same as those described above. In addition, although each embodiment is described above individually, this does not mean that the measures in the respective embodiments can not be used in combination with each other.

The embodiments of the present disclosure have been described above. However, these embodiments are for illustrative purposes only and are not intended to limit the scope of the present disclosure. The scope of the disclosure is defined by the appended claims and their equivalents. Many alternatives and modifications can be made by those skilled in the art without departing from the scope of the present disclosure, which should all fall within the scope of the present disclosure.

1. A semiconductor device comprising:
a semiconductor substrate with a fin;
a gate intersecting with the fin and a source region and a drain region within the fin at both sides of the gate;
metal silicides formed at the source region and the drain region and in contact with the source region and the drain region respectively;
wherein there is a impurity dopant at a interface of the metal silicide in contact with the source/drain region, which is capable of reducing a Schottky barrier height between the metal silicide and the source/drain region.

2. The semiconductor device according to claim 1, wherein the impurity dopant comprises at least one selected from the group consisting of C, Ge, N, P, As, O, S, Se, Te, F, Cl.

3. The semiconductor device according to claim 1, wherein the gate comprises a high-K gate dielectric and a metal gate conductor.

4. The semiconductor device according to claim 1, wherein the metal silicide comprises titanium silicide.

5. The semiconductor device according to claim 1, wherein the source region and the drain region comprise n-type doped silicon.

6. A method of manufacturing a semiconductor device, comprising:
forming a fin on a semiconductor substrate;
forming a gate intersecting with the fin;
forming a source region and a drain region in the fin at both sides of the gate;
depositing a dielectric on the fin;
etching the dielectric to form a contact trench over the source region and the drain region respectively, thereby exposing at least a portion of the upper surface of the source region and the drain region;
making an amorphization process on at least part of the exposed upper surface through the contact trench;
making an impurity dopant implantation to the at least part of the exposed upper surface through the contact trench;
depositing a metal in the contact trench and performing an anneal to form a metal silicide after the impurity dopant implantation;
wherein the impurity dopant is capable of reducing a Schottky barrier height between the metal silicide and the source/drain region.

7. The method according to claim 6, wherein the implanted impurity dopant is segregated at the interface between the metal silicide and the source/drain region during annealing so as to reduce the Schottky barrier height between the metal silicide and the source/drain region.

8. The method according to claim 6, wherein the segregated impurity dopant is at least one selected from the group consisting of C, Ge, N, P, As, O, S, Se, Te, F, Cl.

9. The method according to claim 6, wherein the gate comprises a high-K gate dielectric and a metal gate conductor.

10. The method according to claim 6, wherein the deposited metal comprises Ti/TiN and the metal silicide comprises titanium silicide.

11. The method according to claim 6, wherein the source region and the drain region comprise n-type doped silicon.

12. The method according to claim 6, wherein the annealing comprises rapid thermal annealing, laser annealing, and/or dynamic surface annealing.

13. The method according to claim 6, wherein the amorphization process comprises making a germanium implantation.

14. The method according to claim 10, further comprising:
depositing tungsten (W) in the contact trench to form a tungsten layer on the Ti/TiN;
performing CMP to planarize the upper surface of the tungsten layer.

15. The method according to claim 11, wherein the amorphous silicon region formed after the amorphization process has a depth of 10 nm or less.

16. The method according to claim 15, wherein the impurity dopant is implanted into the amorphous silicon region.

17. The method according to claim 16, wherein most of the implanted impurity dopants are confined in the amorphous silicon region.

18. The method according to claim 15, further comprising:
at least a portion of the amorphous silicon regrows into crystalline silicon during annealing.

19. The method according to claim 15, further comprising:
the amorphous silicon disappears by reacting with the deposited metal and/or by solid-phase epitaxial regrowth (SPER) after annealing.

20. The method according to claim 6, wherein the implantation energy for impurity dopant implantation is between 0.5 keV and 5 keV.
